(19) United States
(12) Patent Application Publication
(10) Pub. No.: US 2026/0190784 A1
(43) Pub. Date: Jul. 2, 2026

(54) DISPLAY DEVICE, METHOD OF MANUFACTURING THE SAME AND ELECTRONIC DEVICE INCLUDING THE SAME

(71) Applicant: Samsung Display Co., Ltd., Yongin-Si (KR)

(72) Inventor: Seok Hoon SEO, Yongin-si (KR)

(21) Appl. No.: 19/407,501

(22) Filed: Dec. 3, 2025

(30) Foreign Application Priority Data
Dec. 27, 2024 (KR) 10-2024-0198485

(51) Int. Cl. H10K 59/80; H10K 59/12; H10K 59/88

(52) U.S. Cl. CPC H10K 59/873; H10K 59/1201; H10K 59/88

(57) ABSTRACT

A display device includes a substrate including a display area, an opening and a non-display area between the opening and the display area, a display element disposed on the display area of the substrate, an organic insulation layer and an inorganic insulation layer stacked on the non-display area of the substrate, and a gap-fill pattern disposed on an end portion of the non-display area adjacent to the opening of the substrate. The gap-fill pattern is in contact with at least one end portion of the organic insulation layer and the inorganic insulation layer.

### CROSS-REFERENCE TO RELATED APPLICATION

This application claims priority to Korean Patent Application No. 10-2024-0198485 filed on Dec. 27, 2024 in the Korean Intellectual Property Office (KIPO), the entire disclosure of which is incorporated by reference herein.

### BACKGROUND

### 1. Field

Embodiments of the present disclosure relate to a display device, a method of manufacturing the same and an electronic device including the same. More particularly, embodiments of the present disclosure relate to a display device including a display region and a functional region, a method of manufacturing the same and an electronic device including the same.

### 2. Description of the Related Art

In a display device such as an organic light emitting diode (OLED) display device and a liquid crystal display device (LCD), a display substrate including thin film transistors (TFTs) and various wirings may be provided. A display structure including electrodes and emission layers may be formed on the display substrate.

Recently, a functional element including a sensor element such as a camera and an optical element has been combined with the display device.

### SUMMARY

According to an aspect of the present disclosure, a display device having

improved mechanical and optical reliability is provided.

According to an aspect of the present disclosure, a method of manufacturing a display device having improved mechanical and optical reliability is provided.

According to an aspect of the present disclosure, an electronic device including a display device with improved mechanical and optical reliability is provided.

According to an embodiment, a display device includes a substrate including a display area, an opening and a non-display area between the opening and the display area, a display element disposed on the display area of the substrate, an organic insulation layer and an inorganic insulation layer stacked on the non-display area of the substrate, and a gap-fill pattern disposed on an end portion of the non-display area adjacent to the opening of the substrate. The gap-fill pattern is in contact with at least one end portion of the organic insulation layer and the inorganic insulation layer.

In an embodiment, the opening may penetrate the substrate and may extend along an outer sidewall of the gap-fill pattern.

In an embodiment, the gap-fill pattern may have a hollow cylindrical shape.

In an embodiment, the gap-fill pattern may contact a top surface of the substrate.

In an embodiment, the inorganic insulation layer may include an encapsulation layer covering the display element on the display area, and the gap-fill pattern may be in contact with an end portion of the encapsulation layer.

In an embodiment, the organic insulation layer may include an overcoating layer formed on the encapsulation layer, and the gap-fill pattern may be in contact with a side surface of the overcoating layer.

In an embodiment, the display device may include a dam structure and a tip structure arranged on the non-display area of the substrate. The encapsulation layer may cover the dam structure and the tip structure.

In an embodiment, the display element may include a pixel electrode, a counter electrode, and a light-emitting portion between the pixel electrode and the counter electrode. A residual layer of the counter electrode and a residual layer of the light-emitting portion may remain under the encapsulation layer on an end portion of the non-display area, and the gap-fill pattern may cover side surfaces of the residual layers of the counter electrode and the light-emitting portion.

In an embodiment, the organic insulation layer may include a planarization layer arranged on the encapsulation layer, and the planarization layer may commonly cover the display area and the non-display area.

In an embodiment, the gap-fill pattern may partially cover a top surface of the planarization layer.

In an embodiment, the organic insulation layer or the inorganic insulation layer may include a stepped portion on an end portion of the non-display area adjacent to the opening of the substrate, and the gap-fill pattern may cover the stepped portion.

According to an embodiment, a method of manufacturing a display device includes preparing a preliminary display device that comprises a substrate including a display area and a dummy area, wherein a display element is formed on the display area of the substrate, forming a gap-fill layer at least partially filling the dummy area, partially etching the substrate to form an etched region overlapping the gap-fill layer, and partially removing the gap-fill layer to form an opening connecting to the etched region of the substrate.

In an embodiment, the substrate may include a non-display area between the display area and the dummy area, and the preliminary display device may include a stacked structure of an organic insulation layer and an inorganic insulation layer formed on the non-display area.

In an embodiment, the method may further include removing a portion of the stacked structure around a boundary between the non-display area and the dummy area by a first partial removal process to form a first sub-opening. The gap-fill layer may fill the first sub-opening.

In an embodiment, the method may further include irradiating a laser from a bottom surface of the substrate to form an etching line overlapping the first sub-opening before forming the gap-fill layer. Forming the etched region may include supplying an etching solution through the etching line to form the etched region.

In an embodiment, partially removing the gap-fill layer to form the opening may include removing a portion of the gap-fill layer overlapping the etched region by a second partial removal process to form the opening.

In an embodiment, forming the opening may include separating the dummy area using the second sub-opening and the etched region.

In an embodiment, a gap-fill pattern remaining from the gap-fill layer by the second partial removal process may be formed on an end portion of the non-display area of the substrate.

In an embodiment, the first partial removal process and the second partial removal process may be performed using a laser ablation.

According to an embodiment, an electronic device incudes a display device, a memory, and a processor executing data included in the memory and configured to control an operation of the display device. The display device includes a substrate including a display area, an opening and a non-display area between the opening and the display area, a display element disposed on the display area of the substrate, an organic insulation layer and an inorganic insulation layer stacked on the non-display area of the substrate, and a gap-fill pattern disposed on an end portion of the non-display area adjacent to the opening of the substrate. The gap-fill pattern is in contact with at least one end portion of the organic insulation layer and the inorganic insulation layer.

According to embodiments of the present disclosure, a gap-fill layer may be used in the formation of an opening to prevent damages to layers, structures, etc., of a display device due to an etching solution. Additionally, the gap-fill layer may be partially removed to prevent delamination of the display device from occurring when forming the opening.

According to embodiments of the present disclosure, reliability of a structure around the opening may be improved by the gap-fill pattern around the opening.

### BRIEF DESCRIPTION OF THE DRAWINGS

FIG. 1 is a schematic perspective view illustrating a display device according

to embodiments.

FIG. 2 is a partially enlarged plan view schematically illustrating a portion around an opening of a display device according to embodiments.

FIG. 3 is a schematic cross-sectional view illustrating a display device according to embodiments.

FIG. 4 is a schematic cross-sectional view illustrating a display device according to embodiments.

FIGS. 5 to 10 are schematic cross-sectional views for describing a method of manufacturing a display device according to embodiments.

FIG. 11 is a schematic perspective view illustrating a method of manufacturing a display device according to embodiments.

FIGS. 12 to 15 are schematic cross-sectional views for describing a method of manufacturing a display device according to embodiments.

FIG. 16 is a block diagram of an electronic device according to an embodiment.

FIG. 17 is schematic diagrams of electronic devices according to embodiments.

### DETAILED DESCRIPTION OF THE EMBODIMENTS

Hereinafter, embodiments of the present invention will be described in more detail with reference to the accompanying drawings. The same reference numerals may refer to the same elements in the drawings, and repeated descriptions of the same elements may be omitted. Embodiments disclosed in the drawings are exemplary, and is to be understood to include all modifications, equivalents and substitutes included in the spirit and technical scope of the present invention.

The terms “on”, “connected”, “coupled,” etc., used herein may refer to not only a direct placement/connection/combination, but also refer to a case where another element is interposed between two different elements.

The terms such as “first”, “second”, “below”, “lower”, “upper”, “above,” etc., are used in a relative sense to distinguish one element or position from other element or position, and do not specify an absolute position or an absolute order.

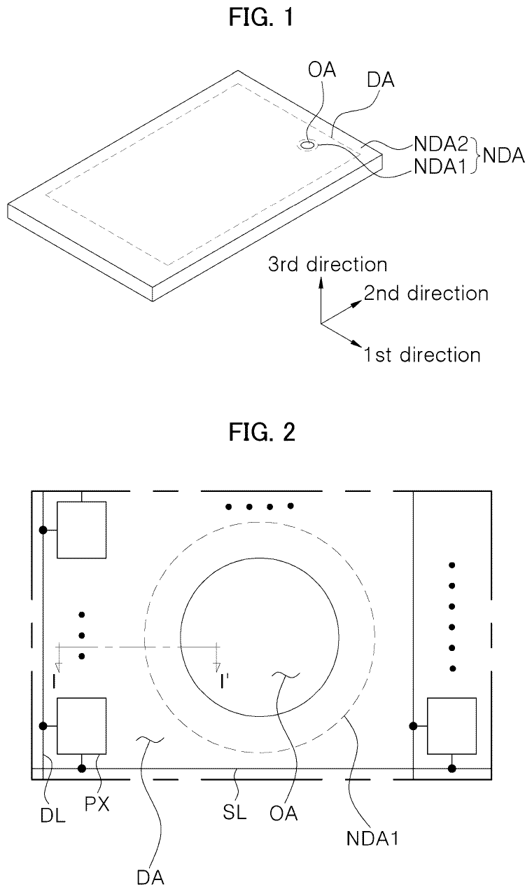

FIG. 1 is a schematic perspective view illustrating a display device according to embodiments.

In FIG. 1, a first direction and a second direction may refer to two directions perpendicular to each other and parallel to a display surface of a display device. For example, the first direction may correspond to an X-direction (a row direction), and the second direction may correspond to a Y-direction (a column direction) of the display device. The third direction may be perpendicular to the first direction and the second direction. The third direction may correspond to a Z-direction (a thickness direction) of the display device.

The above definitions of the directions may be equally applied to the accompanying drawings.

Referring to FIG. 1, the display device may include a display area DA and a non-display area. The non-display area may include a first non-display area NDA1 and a second non-display area NDA2.

According to embodiments, the display area DA may include a display element such as a light-emitting element that emits light. The second non-display area NDA2 may include a peripheral portion of the display device. In an embodiment, the second non-display area NDA2 may include a light-shielding portion or a bezel portion of the display device.

The display device according to embodiments may include an opening OA. The opening OA may have a hole shape formed in the display area DA. The first non-display area NDA1 may be disposed around the opening OA. In an embodiment, the first non-display area NDA1 may have a ring shape surrounding the opening OA.

For example, the first non-display area NDA1 may surround at least a portion of the opening OA. In an embodiment, the first non-display area NDA1 may entirely surround the opening OA in a plan view. The display area DA may surround at least a portion of the first non-display area NDA1. In an embodiment, the display area DA may entirely surround the first non-display area NDA1 in the plan view.

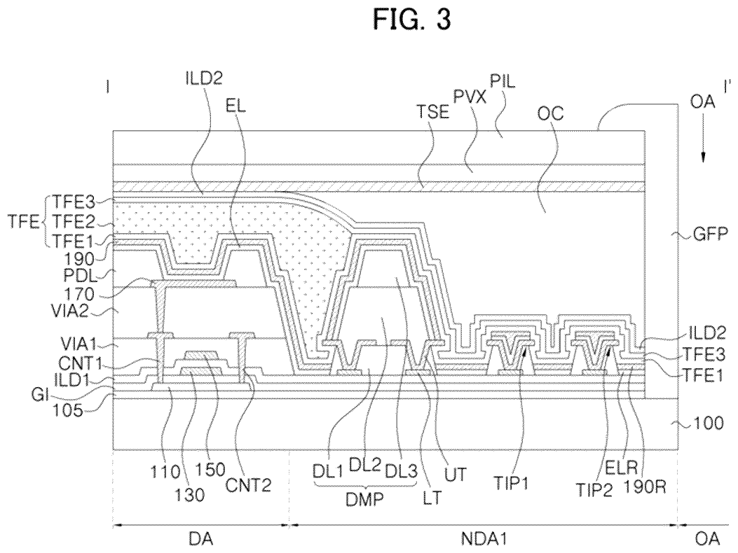

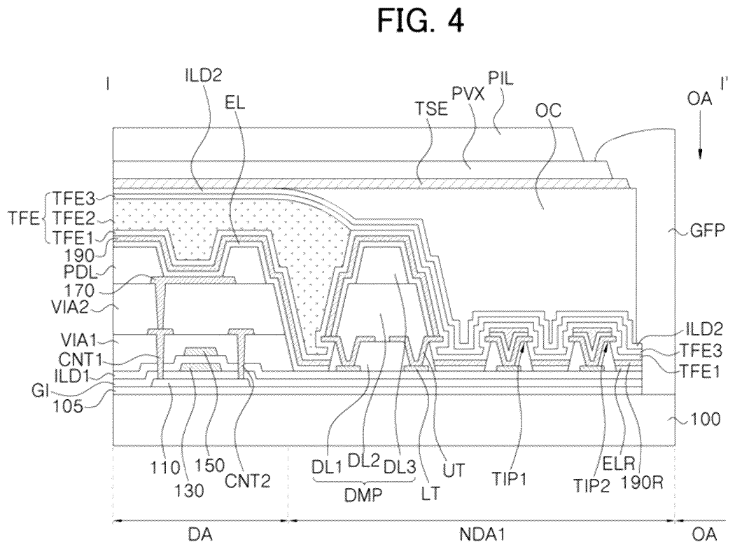

A top surface of the display device illustrated in FIG. 1 may correspond to a window surface. For example, a window substrate may be placed on a display panel illustrated in FIG. 3 or FIG. 4, and the window substrate may cover the opening OA.

FIG. 2 is a partially enlarged plan view schematically illustrating a portion around an opening of a display device according to embodiments.

According to embodiments, a pixel circuit including scan lines (or gate lines) SL and data lines DL may be arranged on a substrate 100 (see FIG. 3) of the display device. For example, the scan line SL may extend in the first direction, and the data line DL may extend in the second direction.

Each of pixels PX may be connected to a corresponding scan line among a plurality of the scan lines SL and a corresponding data line among a plurality of the data lines DL.

Each of the pixels PX may further include a pixel circuit including a transistor and a display element such as a light-emitting device as will be described later. Although not illustrated in detail in FIG. 2, the pixel circuit may further include wirings such as a power line and a ground line.

The pixels PX may be arranged in the display area DA. The pixels PX may not be arranged in the first non-display area NDA1. A tip structure TIP and/or a dam structure DMP may be disposed in the first non-display area NDA1 as will be described later, and the first non-display area NDA1 may serve as a buffer area for blocking diffusion of moisture/impurities between the opening OA and the display area DA.

In an embodiment, the scan line SL and the data line DL may not extend to the first non-display area NDA1 and the opening OA. For example, the scan line SL and the data line DL may bypass the first non-display area NDA1 by extending along an outside around the first non-display area NDA1.

In an embodiment, the scan line SL and the data line DL may extend along an inner side of a circumference of the first non-display area NDA1 to bypass the opening OA.

Although not illustrated in detail in FIGS. 1 and 2, a peripheral circuit may be disposed in the second non-display area NDA2. For example, the peripheral circuit may include a gate driver. The gate driver may be integrated into a display device through an oxide semiconductor gate (OSG) driver circuit process, an amorphous silicon gate (ASG) driver circuit process, or a polysilicon gate (PSG) driver circuit process. The peripheral circuit may further include a data driver, a light-emitting driver, a power voltage generator, a timing controller, or the like.

Hereinafter, the display device of the present disclosure may be described as including an organic light-emitting display device for only the purpose of the description. However, the present disclosure is not limited thereto. For example, the display device according to an embodiment may be any type of display device including an inorganic light-emitting display device, a quantum dot light-emitting display device, or the like.

FIG. 3 is a schematic cross-sectional view illustrating a display device according to embodiments. Specifically, FIG. 3 is a cross-sectional view taken along a line I-I′ of FIG.. 2 in the third direction.

Referring to FIG. 3, the display device may include the substrate 100 and a circuit structure, a display element, and a non-display stacked structure disposed on the substrate 100.

As described above, the display device may include the display area DA, the first non-display area NDA1, the second non-display area NDA2, and the opening OA. Accordingly, the substrate 100 may also be divided into the display area DA, the first non-display area NDA1, the second non-display area NDA2, and an opening area in which the opening OA may be formed.

The circuit structure and the display element may be disposed on the display area DA of the substrate 100. The circuit structure may include a transistor electrically connected to the display element to control switching/driving of the display element. The circuit structure may further include wirings such as the scan line SL, the data line DL, a power line, a ground line, or the like.

The non-display stacked structure may be disposed on the first non-display area NDA1 of the substrate 100.

The substrate 100 may serve as a back-plane substrate of the display device. A glass substrate or a plastic substrate may be used as the substrate 100. In an embodiment, the glass substrate may be used as the substrate 100.

A buffer layer 105 may be disposed on a top surface of the substrate 100. The buffer layer 105 may prevent moisture and impurities penetrating through the substrate 100 from being diffused into the circuit structure and the display element on the substrate. The buffer layer 105 may be formed throughout the display area DA and the first non-display area NDA1 of the substrate 100.

The buffer layer 105 may include an inorganic insulating material such as, e.g., silicon oxide, silicon nitride or silicon oxynitride. These may be used alone or in a combination thereof. For example, the buffer layer 105 may have a stacked structure including a silicon oxide layer and a silicon nitride layer.

The buffer layer 105 may be formed through a deposition process such as a chemical vapor deposition (CVD) process, a sputtering process, an atomic layer deposition (ALD) process, or the like, to include the above-described inorganic insulating material.

However, the present disclosure is not limited thereto. For example, the buffer layer 105 may include an organic layer, and may have a multi-layered structure of an organic layer and an inorganic layer.

The buffer layer 105 may be formed on the top surface of the substrate 100 throughout the display area DA and the first non-display area NDA1.

The transistor may include an active layer 110 and a gate electrode 130. A gate insulation layer GI may be formed between the active layer 110 and the gate electrode 130.

The active layer 110 may be disposed on the buffer layer 105, and may be patterned by, e.g., a photo-lithography process so as to be repeatedly/regularly arranged in each pixel. The active layer 110 may include a silicon compound such as amorphous silicon or polysilicon.

The active layer 110 may include an oxide semiconductor such as indium gallium zinc oxide (IGZO), zinc tin oxide (ZTO), or ITZO.

A p-type dopant or an n-type dopant may be doped in a partial region of the active layer 110, so that the active layer 110 may include a source region, a drain region, and a channel region.

The gate insulation layer GI may be formed on the active layer 110, and the gate electrode 130 may be placed on the gate insulation layer GI. As illustrated in FIG. 3, the gate insulation layer GI may be commonly formed on the display area DA and the first non-display area NDA, and may be commonly included in a plurality of the pixels or a plurality of the transistors.

However, the present disclosure is not limited thereto. For example, the gate insulation layer GI may be independently patterned for each pixel. In this case, the gate insulation layer GI may be formed by being etched together with the gate electrode 130.

The gate electrode 130 may overlap the channel region of the active layer 110 in the third direction. A scan signal may be transmitted from the scan line SL through the gate electrode 130.

The gate insulation layer GI may be formed by the above-mentioned deposition process and include an inorganic insulating material such as silicon oxide, silicon nitride or silicon oxynitride.

The source region and the drain region may be formed in the active layer 110 by using the gate electrode 130 as an ion implantation mask.

A first insulating interlayer ILD1 covering the gate insulation layer GI and the gate electrode 130 may be formed on the active layer 110. The first insulating interlayer ILD1 may be commonly and continuously formed throughout the display area DA and the first non-display area NDA1.

The first insulating interlayer ILD1 may be formed by the above-mentioned deposition process and include an inorganic insulating material such as silicon oxide, silicon nitride or silicon oxynitride. The first insulating interlayer ILD1 may be formed in a single-layered structure or a multi-layered structure including different materials.

In an embodiment, an overlapping electrode 150 may be disposed on the first insulating interlayer ILD1. The overlapping electrode 150 may overlap the gate electrode 130 in the third direction, and a storage capacitor may be formed between the overlapping electrode 150 and the gate electrode 130 facing each other. For example, a first metal layer may be formed on the first insulating interlayer ILD1, and then may be partially etched to form the overlapping electrode 150.

A first via insulation layer VIA1 covering the overlapping electrode 150 may be formed on the first insulating interlayer ILD1. The first via insulation layer VIA1 may serve as a planarization layer in the display area DA.

A first contact electrode CNT1 and a second contact electrode CNT2 may extend through the first via insulation layer VIA1 to be in contact with or connected to the drain region and the source region of the active layer 110, respectively. The first contact electrode CNT1 and the second contact electrode CNT2 may penetrate the first via insulation layer VIA1 and the first insulating interlayer ILD1, and may also penetrate the gate insulation layer GI.

According to an embodiment, contact holes may be formed by partially etching the first via insulation layer VIA1, the first insulating interlayer ILD1, and the gate insulation layer GI. For example, the contact holes exposing the source region and the drain region, respectively, may be formed.

A second metal layer filling the contact holes may be formed on the first via insulation layer VIA1, and then the second metal layer may be partially etched to form the first contact electrode CNT1 and the second contact electrode CNT2. For example, a data signal may be transferred from the data line DL through the second contact electrode CNT2.

A second via insulation layer VIA2 covering the contact electrodes CNT1 and CNT2 may be formed on the first via insulation layer VIA1. For example, a pixel electrode 170 extending through the second via insulation layer VIA2 and being in contact with or electrically connected to the first contact electrode CNT1 may be formed on the second via insulation layer VIA2.

According to an embodiment, the second via insulation layer VIA2 may be partially etched to form a via hole exposing a top surface of the first contact electrode CNT1. A third metal layer filling the via hole may be formed on the second via insulation layer VIA2, and the third metal layer may be partially etched to form the pixel electrode 170.

The first and second via insulation layers VIA1 and VIA2 may include an organic material such as polyimide, an epoxy resin, an acrylic resin, polyester, a siloxane resin, benzocyclobutene (BCB), or the like. The first and second via insulation layers VIA1 and VIA2 may be formed through a coating process such as a spin coating process.

The gate electrode 130, and the first to third metal layers may include a metal such as Ag, Mg, Al, W, Cu, Ni, Cr, Mo, Ti, Pt, Ta, Nd, Sc, or an alloy thereof. The gate electrode 130 and the first to third metal layers may be formed through a deposition process such as a sputtering process.

The pixel electrode 170 may serve as an anode, and may include a high work function conductive material that may promote hole injection. The pixel electrode 170 may be formed as a transmissive electrode. The pixel electrode 170 may include a transparent conductive oxide such as indium tin oxide (ITO), indium zinc oxide (IZO), zinc oxide (ZnO), indium tin oxide (ITZO), or the like.

The pixel electrode 170 may be formed as a translucent electrode or a reflective electrode. The pixel electrode 170 may include a metal selected from Ag, Mg, Cu, Al, Pt, Pd, Au, Ni, Nd, Ir, Cr, Li, Li, Ca, Mo, Ti, W, In, Sn and Zn, or an alloy or a compound (e.g., LiF) including at least one therefrom.

The pixel electrode 170 may have a single-layered structure or a multi-layered structure. For example, the pixel electrode 170 may have a triple-layered structure of ITO/Ag/ITO.

A pixel defining layer PDL exposing a top surface of the pixel electrode 170 may be formed on the second via insulation layer VIA2. The pixel or the light-emitting region in which the top surface of the pixel electrode 170 is at least partially exposed may be defined by the pixel defining layer PDL. The pixel defining layer PDL may overlap edges of the pixel electrode 170. For example, the pixel or the light-emitting region may be defined by a sidewall of the pixel defining layer PDL, which may be referred to as an opening of the pixel defining layer PDL.

The pixel defining layer PDL may include, e.g., an organic material such as a polysiloxane resin, a polyimide resin, an acrylic resin, or the like. The pixel defining layer PDL may include a light absorbing material such as a black pigment/dye dispersed in a resin material.

A light-emitting portion EL may be disposed on the exposed top surface of the pixel electrode 170. The light-emitting portion EL may include an organic emission layer including an organic light-emitting material that may emit lights having different colors in each of a red pixel, a green pixel and a blue pixel. For example, the light-emitting portion EL may be commonly disposed on the display area DA, as illustrated in FIG. 4. However, the present disclosure is not limited thereto. For example, the light-emitting portion EL may be disposed in the opening of the pixel defining layer PDL.

For example, the organic light-emitting material may include a host material excited by holes and electrons, and a dopant material increasing a luminous efficiency by absorption and release of energy.

In an embodiment, the light-emitting portion EL may include an emission layer (EML), and may further include a hole transport region between the pixel electrode 170 and the emission layer. The hole transport region may include a hole transport layer (HTL) and/or a hole injection layer (HIL).

The light-emitting portion EL may further include an electron transport region disposed on the emission layer. The electron transport region may include an electron transport layer (ETL) and/or an electron injection layer (EIL).

For example, the hole transport region may include a hole transporting material such as m-MTDATA (4,4′,4″-[tris(3-methylphenyl)phenylamino]triphenylamine), TDATA (4,4′4″-tris(N,N-diphenylamino)triphenylamine), 2-TNATA (4,4′,4″-tris[N(2-naphthyl)-N-phenylamino]-triphenylamine), NPB (N,N′-di(naphthalene-1-yl)-N,N′-diphenyl-benzidine), TPD (N,N′-bis(3-methylphenyl)-N,N′-diphenyl-[1,1′-biphenyl]-4,4′-diamine), TCTA (4,4′,4″-tris(N-carbazolyl)triphenylamine), PEDOT/PSS (poly(3,4-ethylenedioxythiophene)/poly(4-styrenesulfonate)), or the like.

For example, the electron transport region may include an electron transporting material such as an anthracene-based compound, Alq₃ (tris(8-hydroxyquinolinato)aluminum), TPBi (1,3,5-Tri(1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tert-butylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAlq (bis(2-methyl-8-quinolinolato-N1,O8)-(1,1′-biphenyl-4-olato)aluminum), or the like.

The hole transport region and the electron transport region may commonly and continuously extend throughout a plurality of the light-emitting areas or the pixels. However, the present disclosure is not limited thereto. For example, the organic emission layer may be independently patterned for each pixel, and may extend from the display area DA to the first non-display area NDA1 together with the hole transport region and the electron transport region in the pixel PX adjacent to the first non-display area NDA1.

The light-emitting portion EL may be formed through a process such as a thermal deposition, a vacuum deposition, a spin coating, an inkjet printing, a laser printing, a casting, a laser thermal transfer, or the like.

A counter electrode 190 may be disposed on the pixel defining layer PDL and the light-emitting portion EL. The counter electrode 190 may be formed on top surfaces of the pixel defining layer PDL and the electron transfer region.

The counter electrode 190 may serve as a common electrode continuously and commonly extending throughout a plurality of the light-emitting areas or the pixels. For example, the counter electrode 190 may extend from the display area DA to the first non-display area NDA1.

The counter electrode 190 may be referred to as an electron injection electrode or a cathode. The counter electrode 190 may include a metal, an alloy, an electrically conductive compound, and the like having a low work function.

For example, the counter electrode 190 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or the like. These may be used alone or in a combination thereof.

The counter electrode 190 may include a transmissive electrode, a translucent electrode, or a reflective electrode. The counter electrode 190 may have a single-layered structure or a multi-layered structure.

The display element may include the pixel electrode 170, the light-emitting portion EL and the counter electrode 190 as described above. According to an embodiment, the display element may be a light-emitting element such as an OLED element. The display element may be electrically connected to each transistor through, e.g., the first contact electrode CNT1, and may be provided in each pixel PX.

The non-display stacked structure disposed on the first non-display area NDA1 of the substrate 100 may include a dam structure DMP. The non-display stacked structure may further include a tip structure TIP1 and TIP2.

According to embodiments illustrated in FIG. 3, the dam structure DMP may include a first dam layer DL1 and a second dam layer DL2. The first dam layer DL1 and the second dam layer DL2 may be sequentially stacked from the top surface of the substrate 100 or the first insulating interlayer ILD1.

In an embodiment, the dam structure DMP may further include a third dam layer DL3 stacked on the second dam layer DL2. The first dam layer DL1, the second dam layer DL2, and the third dam layer DL3 may include an organic insulating material. Each of the first dam layer DL1, the second dam layer DL2, and the third dam layer DL3 may be formed by being etched from an organic insulation layer substantially the same as those of the first via insulating layer VIA1, the second via insulating layer VIA2, and the pixel defining layer PDL, respectively.

A tip portion may protrude from a sidewall of the dam structure DMP. For example, a tip structure including a lower pattern LT and an upper pattern UT may be included in the dam structure. Each of the lower pattern LT and the upper pattern UT may be formed by being etched from the first metal layer and the second metal layer, respectively. For example, one end portion of the upper pattern UT may protrude from the sidewall of the dam structure DMP.

A plurality of the dam structures DMP and the tip structure TIPs may be arranged on the first non-display area NDA1 (e.g., between the display area DA and the opening OA). For convenience of illustration, one dam structure DMP and two tip structures TIP1 and TIP2 are illustrated in FIG. 3, but the present inventive concepts are not limited to the embodiment illustrated in FIG. 3.

For example, two or more dam structures DMP may be arranged between the first tip structure TIP1 and the display area DA in the first non-display area NDA1. Additionally, a plurality of (e.g., three or more, four or more, five or more, six or more, seven or more, or eight or more) the tip structures may be arranged between the dam structure DMP and the opening OA.

The tip structure TIP1 and TIP2 may include the lower pattern LT and the upper pattern UT, and may include the first dam layer DL1 covering the lower pattern LT and supporting the upper pattern UT. Both end portions of the upper pattern UT may protrude in a horizontal direction on the top surface of the first dam layer DL1.

An encapsulation layer TFE may be formed on the display area DA and the first non-display area NDA1 of the substrate 100. The encapsulation layer TFE may cover the pixel defining layer PDL and the display element in the display area DA. The encapsulation layer TFE may protect the display elements from moisture or oxygen. The encapsulation layer TFE may be formed on top surfaces of the pixel defining layer PDL and the counter electrode 190 in the display area DA.

The encapsulation layer TFE may include an inorganic insulation layer including silicon nitride (SiNx), silicon oxide (SiOx), indium tin oxide, indium zinc oxide, or any combination thereof, an organic insulation layer including polyethylene terephthalate, polyethylene naphthalate, polycarbonate, polyimide, polyethylene sulfonate, polyoxymethylene, polyarylate, hexamethyldisiloxane, an acrylic resin (e.g., polymethylmethacrylate, polyacrylic acid, etc.), an epoxy resin (e.g., aliphatic glycidyl ether (AGE)) or any combination thereof, or a combination of the inorganic insulation layer and the organic insulation layer.

According to an embodiment, the encapsulation layer TFE may include a first encapsulation layer TFE1, a second encapsulation layer TFE2 and a third encapsulation layer TFE3 sequentially stacked from the top surfaces of the pixel defining layer PDL and the counter electrode 190. The first encapsulation layer TFE1 and the third encapsulation layer TFE3 may be inorganic insulation layers including the inorganic insulating material, and may be formed by a deposition process such as a CVD process.

The second encapsulation layer TFE2 may be an organic insulation layer formed by a coating process such as a spin coating process to include the above-mentioned organic insulating material. A thickness of the second encapsulation layer TFE2 may be greater than each thickness of the first encapsulation layer TFE1 and the third encapsulation layer TFE3.

According to an embodiment, the encapsulation layer TFE may commonly cover the display area DA and the first non-display area NDA1. The encapsulation layer TFE may cover the dam structure DMP and the tip structure TIP1 and TIP2 in the first non-display area NDA1.

In an embodiment, the second encapsulation layer TFE2 may not be arranged in the first non-display area NDA1 and may be blocked by the dam structure DMP adjacent to the opening OA. For example, the second encapsulation layer TFE2 may be blocked by an outermost dam structure DMP adjacent to the opening OA among a plurality of the dam structures DMP, and the second encapsulation layer TFE2 is not disposed on an upper surface and a side surface, which is close to the opening OA, of the dam structure DMP. However, the present disclosure is not limited thereto. For example, the second encapsulation layer TFE2 may substantially completely cover at least one dam structure DMP (e.g., a dam structure adjacent to the display area DA) among a plurality of the dam structures DMP.

The first encapsulation layer TFE1 and the third encapsulation layer TFE3 may be continuously formed over the display area DA and the first non-display area NDA1, and may be formed along a sidewall of the pixel defining layer PDL, sidewalls of the via insulation layers VIA2 and VIA1, the top surface of the first insulating interlayer ILD1, a surface of the dam structure DMP, and surfaces of the tip structures TIP1 and TIP2.

The third encapsulation layer TFE3 may contact the first encapsulation layer TFE on the top surface of the dam structure DMP, after the second encapsulation layer TFE2 is blocked by the dam structure DMP, and may extend together with the first encapsulation layer TFE in the first non-display area NDA1.

According to an embodiment, the light-emitting portion EL and the counter electrode 190 may extend from the display area DA to the first non-display area NDA1, and may be discontinuously cut by the tip portion included in the dam structure DMP and the tip structures TIP1 and TIP2. For example, as illustrated in FIG. 3, the light-emitting portion EL and the counter electrode 190 may remain as residual layers under the tip portion of the dam structure DMP and the tip structures TIP1 and TIP2, and may be placed on the surface of the dam structure DMP above the tip portion, and on top surfaces of the tip structures TIP1 and TIP2. The light-emitting portion EL and the counter electrode 190 present in the first non-display area NDA1 may be covered by the first encapsulation layer TFE1.

In an embodiment, a second insulating interlayer ILD2 may be formed on the encapsulation layer TFE or the third encapsulation layer TFE3. The second insulating interlayer ILD2 may be formed by a deposition process such as a CVD process to include an inorganic insulating material substantially the same as or similar to that of the first insulating interlayer ILD1.

In an embodiment, the second insulating interlayer ILD2 may be formed along a profile of the third encapsulation layer TFE3.

In an embodiment, an overcoating layer OC may be formed on the second insulating interlayer ILD2. The overcoating layer OC may be formed by a coating process such as a spin coating process to include the above-mentioned organic insulating material.

The overcoating layer OC may serve as a planarization layer substantially on the first non-display area NDA1.

In an embodiment, a sensor electrode layer TSE may be formed on the second insulating interlayer ILD2 and the overcoating layer OC. For example, the sensor electrode layer TSE may include touch sensing electrodes for a touch sensing. The sensor electrode layer TSE may be formed as an on-cell type layer, and the second insulating interlayer ILD2 may serve as a support layer, a buffer layer, or an insulating interlayer for forming the sensor electrode layer TSE on the display area DA.

A passivation layer PVX may be formed on the sensor electrode layer TSE. The passivation layer PVX may serve as a protective layer of the sensor electrode layer TSE. The passivation layer PVX may be formed by a deposition process such as a CVD process to include an inorganic insulating material substantially the same as or similar to that of the insulating interlayers ILD1 and ILD2.

Although FIG. 3 illustrates that the passivation layer PVX entirely covers the sensor electrode layer TSE, the passivation layer PVX may partially cover the sensor electrode layer TSE on the first non-display area NDA1.

A planarization layer PIL may cover the passivation layer PVX and the sensor electrode layer TSE. The planarization layer PIL may be an organic insulation layer for planarizing an upper portion of the display panel. The planarization layer PIL may be formed by a coating process such as a spin coating process to include the above-mentioned organic insulating material.

According to an embodiment of the present invention, a gap-fill pattern GFP may be disposed on an end portion of the first non-display area NDA1. An inner side surface (a side surface toward the display area DA) of the gap-fill pattern GFP may be in contact with end portions of the organic insulation layer and the inorganic insulation layer extending to the end portion of the first non-display area NDA1. The gap-fill pattern GFP may include the above-mentioned organic insulating material.

In an embodiment, a light-emitting portion residual layer ELR and a counter electrode residual layer 190R may be sequentially stacked on a portion of the first insulating interlayer ILD1 at the end portion of the first non-display area NDA.

An inorganic layer stack including an inorganic insulating material may be disposed on the counter electrode residual layer 190R. The inorganic layer stack may include the first encapsulation layer TFE1, the third encapsulation layer TFE3, and the second insulating interlayer ILD2.

An organic insulation layer portion including the overcoating layer OC may be disposed on the inorganic layer stack, and end portions of the sensor electrode layer TSE, the passivation layer PVX and the planarization layer PIL may be disposed on the organic insulation layer portion.

The inner side surface of the gap-fill pattern GFP may be in contact with the light-emitting portion residual layer ELR, the counter electrode residual layer 190R, and side surfaces of the inorganic layer stack. The inner side surface of the gap-fill pattern GFP may be in contact with a side surface of the overcoating layer OC. The inner side surface of the gap-fill pattern GFP may be in contact with an end portion or a side surface of the sensor electrode layer TSE.

The inner side surface of the gap-fill pattern GFP may be in contact with an end portion or a side surface of the passivation layer PVX. However, the present disclosure is not limited thereto. For example, the inner side surface of the gap-fill pattern GFP may be spaced apart from the end portion or the side surface of the passivation layer PVX.

The gap-fill pattern GFP may be in contact with a side surface of an end portion of the planarization layer PIL, and may cover a top surface of the end portion of the planarization layer PIL. Accordingly, the gap-fill pattern GFP may be stably fixed to a circumference of the opening OA.

In an embodiment, the inner side surface of the gap-fill pattern GFP may be in contact with an end portion or a side surface of the first insulating interlayer ILD1. The inner side surface of the gap-fill pattern GFP may be in contact with an end portion or a side surface of the gate insulation layer GI. The inner side surface of the gap-fill pattern GFP may be in contact with an end portion or a side surface of the buffer layer 105.

In an embodiment, the gap fill pattern GFP may be in contact with the top surface of the substrate 100.

An outer side surface of the gap-fill pattern GFP may be exposed to the opening OA. Accordingly, a sidewall of the opening OA may be substantially defined by the outer surface of the gap-fill pattern GFP. The opening OA may penetrate the substrate 100. Accordingly, the sidewall of the opening OA may be defined by the outer surface of the gap-fill pattern GFP and a side surface of an end portion of the substrate 100 in the first non-display area NDA1. The gap-fill pattern GFP may have a hollow cylindrical shape formed along the circumference of the opening OA.

According to embodiments of the present disclosure as described above, the circumference of the opening OA may be substantially defined by the gap-fill pattern GFP, and diffusion of impurities/moisture through the opening OA may be blocked. For example, the combination of the dam structure DMP, the tip structure TIP and the gap-fill pattern GFP may more effectively prevent the diffusion of impurities/moisture through the opening OA.

Additionally, the gap-fill pattern GFP may serve as an impact absorbing layer against impacts applied from the opening OA. In an embodiment, the gap-fill pattern GFP may include an organic insulating material having elasticity such as an acrylic resin, an epoxy resin, a silicone resin, or an ester resin as described above.

Thus, a functional element such as a camera and a sensor inserted into the opening OA may be stable protected, and damages to the tip structure TIP1 and TIP2 due to external impact may be prevented or reduced.

As described above, a window substrate may be placed on the planarization layer PIL and the gap-fill pattern GFP to cover the opening OA. In an embodiment, the window substrate may be attached on the planarization layer PIL and the gap-fill pattern GFP using an adhesive layer.

FIG. 4 is a schematic cross-sectional view illustrating a display device according to embodiments. Specifically, FIG. 4 is a cross-sectional view taken along a line I-I′ of FIG. 2 in the third direction.

Detailed descriptions on elements and structures substantially the same as or similar to those described with reference to FIG. 3 are omitted. For example, the display device of FIG. 4 may include substantially the same elements and structures as those of the display device of FIG. 3 except for a stepped structure adjacent to the gap-fill pattern GFP.

Referring to FIG. 4, the organic insulation layer and/or the inorganic insulation layer included in an end portion of the first non-display area NDA1 may form stepped portions, and the gap fill pattern GFP may cover the stepped portions. Accordingly, a sidewall of the opening OA may be formed as a vertical flat surface without substantially no step difference.

In an embodiment, the planarization layer PIL may form the stepped portion with the passivation layer PVX or the sensor electrode layer TSE. The inorganic layer stack may form the stepped portion with the overcoating layer OC.

The gap-fill pattern GFP may cover the stepped portions. In an embodiment, an upper portion of the gap-fill pattern GFP may be spaced apart from the planarization layer PIL. Accordingly, the gap fill pattern GFP and the planarization layer PIL including substantially the same or similar organic insulating material may be prevented from being peeled off together by external impact or damage.

As illustrated in FIGS. 3 and 4, the gap fill pattern GFP and a side surface of the substrate 100 may form a substantially the same continuous vertical surface (or an etching surface), and may define the sidewall of the opening OA.

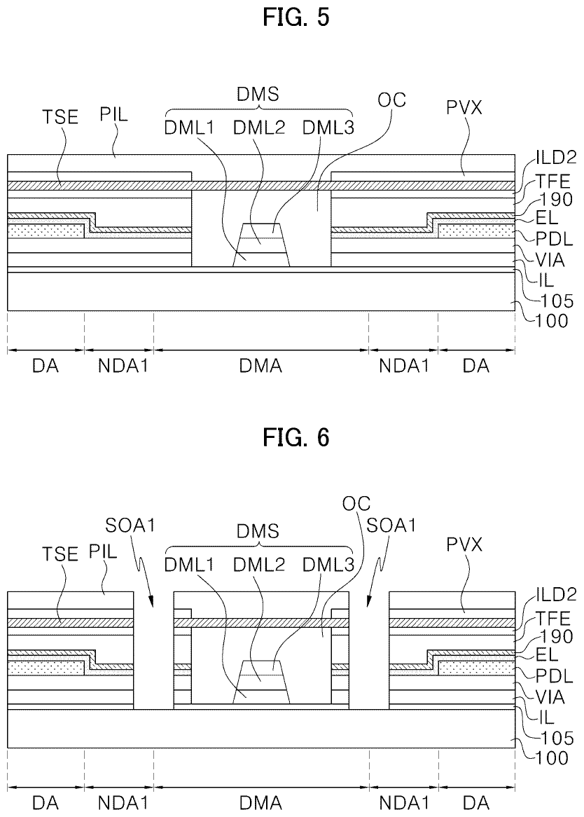

FIGS. 5 to 10 are schematic cross-sectional views for describing a method of manufacturing a display device according to embodiments. Detailed descriptions on elements and structures substantially the same as or similar to those described with reference to FIGS. 3 and 4 are omitted. For convenience of illustration, explanation about the display element, the dam structure DMP, and the tip structure TIP1 and TIP2 are omitted in describing FIGS. 5 to 10.

Referring to FIG. 5, a preliminary display device in which layers and structures described with reference to FIG. 3 are formed on the substrate 100, which includes the display area DA, the first non-display area NDA1, and a dummy area DMA, may be prepared. As used herein, the term “preliminary display device” may refer to a display device structure in a state before the opening OA is formed. The dummy area DMA may be separated or removed from the preliminary display device by a process described later to be converted into the opening OA.

According to an embodiment, an insulation layer IL may be formed throughout the display area DA, the first non-display area NDA1 and the dummy area DMA. The insulation layer IL may include the gate insulation layer GI and the first insulating interlayer ILD1. The insulation layer IL may be a stack of inorganic insulation layers. In an embodiment, the insulation layer IL may further include the buffer layer 105.

In an embodiment, the insulation layer IL may be at least partially removed or may not be present in the dummy area DMA.

The display element including the light-emitting portion EL may be formed in the display area DA, and the pixel defining layer PDL defining the light-emitting portion EL may be formed. A via insulation layer VIA including the first and second via insulation layers VIA1 and VIA2 may be formed between the light-emitting portion EL and the insulation layer IL.

For convenience of descriptions, the via insulation layer VIA is illustrated as being continuously formed in the display area DA and the first non-display area NDA1, but as illustrated in FIG. 3, the via insulation layer VIA may be patterned in the first non-display area NDA1 to form the dam structure DMP.

Additionally, the light-emitting portion EL and the counter electrode 190 are illustrated as being continuously formed in the display area DA and the first non-display area NDA1, but as illustrated in FIG. 3, the light-emitting portion EL and the counter electrode 190 may be discontinued by the tip portion included in the dam structure DMP and the tip structure TIP1 and TIP2.

The encapsulation layer TFE may be formed over the display area DA and the first non-display area NDA1 while covering the light-emitting portion EL. As described with reference to FIG. 3, the second interlayer insulating layer ILD2, the sensor electrode layer TSE, the passivation layer PVX, and the planarization layer PIL may be formed on the encapsulation layer TFE.

A dummy structure DMS may be disposed on a portion of the substrate 100 of the dummy area DMA. In an embodiment, the dummy structure DMS may include a first dummy layer DML1 and a second dummy layer DML2 sequentially disposed on the first dummy layer DML1. For example, the first dummy layer DML1 and the second dummy layer DML2 include an organic insulating material, and may be formed from substantially the same organic insulation layer as that of the first via insulation layer VIA1 and the second via insulation layer VIA2.

The dummy structure DMS may further include a third dummy layer DML3 disposed on the second dummy layer DML2. The third dummy layer DML3 may be formed from an organic insulation layer substantially the same as that of the pixel defining layer PDL.

The overcoating layer OC may cover the dummy structure DMS in the dummy area DMA. For convenience of illustration, FIG. 5 illustrates that the overcoating layer OC is formed only on the dummy area DMA, but, as illustrated in FIG. 3, the overcoating layer OC may also be formed on the first non-display area NDA1.

The planarization layer PIL may be entirely formed over the display area DA, the first non-display area NDA1 and the dummy area DMA, and may cover the dummy structure DMS and the overcoating layer OC.

Referring to FIG. 6, layers around a boundary between the first non-display area NDA1 and the dummy area DMA may be partially removed through a first partial removal process. Accordingly, a first sub-opening SOA1 including the boundary between the first non-display area NDA1 and the dummy area DMA may be formed.

According to an embodiment, portions of the planarization layer PIL, the passivation layer PVX, the sensor electrode layer TSE, the second insulating interlayer ILD2, the encapsulation layer TFE, the counter electrode 190, the light-emitting portion EL, the via insulation layer VIA, the insulation layer IL, or the like, which are included in a boundary region between the first non-display area NDA1 and the dummy area DMA, may be removed by the first partial removal process.

Accordingly, the first sub-opening SOA1 exposing the surface of the substrate 100 may be formed.

In an embodiment, the first partial removal process may include a laser ablation process. For example, layers stacked on the substrate 100 in the boundary region may be removed by irradiating a laser having a predetermined power on an upper portion of the planarization layer PIL at the boundary between the first non-display area NDA1 and the dummy area DMA as described above.

In an embodiment, the first partial removal process may include a photo-lithography process using a photomask. For example, a photoresist exposing the boundary region may be formed on the planarization layer PIL. Thereafter, layers stacked on the substrate 100 may be removed from the boundary region through a dry etching process.

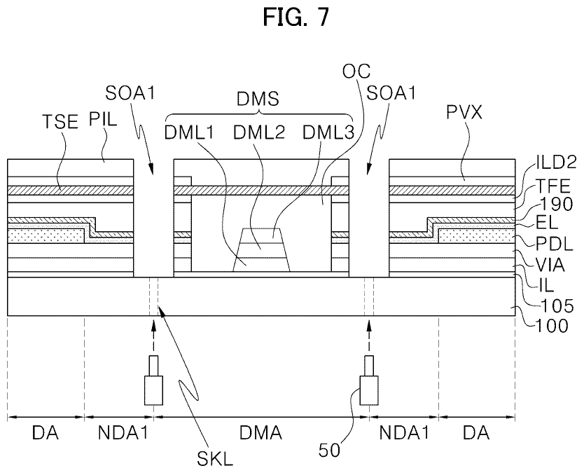

Referring to FIG. 7, an etching line SKL may be formed by irradiating a laser along the boundary between the first non-display area NDA1 and the dummy area DMA from a bottom surface of the substrate 100.

According to an embodiment, a laser light source 50 may be disposed under the bottom surface of the substrate 100 to irradiate the laser. Accordingly, the etching line SKL, which serves as a guide line or a sketch line to which an etching solution is supplied, may be formed.

The etching line SKL may overlap the first sub-opening SOA1. For example, the etching line SKL may be included in the first sub-opening SOA1 in a plan view over the planarization layer PIL.

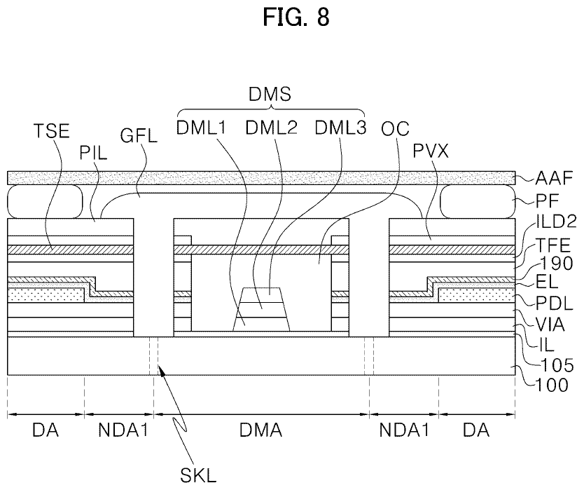

Referring to FIG. 8, a gap-fill layer GFL filling the first sub-opening SOA1 may be formed.

The gap fill layer GFL may be formed to include an organic insulating material such as an acrylic resin, a silicone resin, an epoxy resin, an ester resin, or the like to fill the first sub-opening SOA1. In an embodiment, the gap fill layer GFL may also be formed on a top surface of the planarization layer PIL.

Thereafter, a protective film PF and an acid resistant film AAF may be attached onto the planarization layer PIL. In an embodiment, the protective film PF may be attached to the display area DA to be spaced apart from the gap fill layer GFL.

The protective film PF may serve as a release film. The acid resistant film AAF may be attached on the protective film PF and may serve as a blocking film to prevent leakage of an etchant solution to be described later.

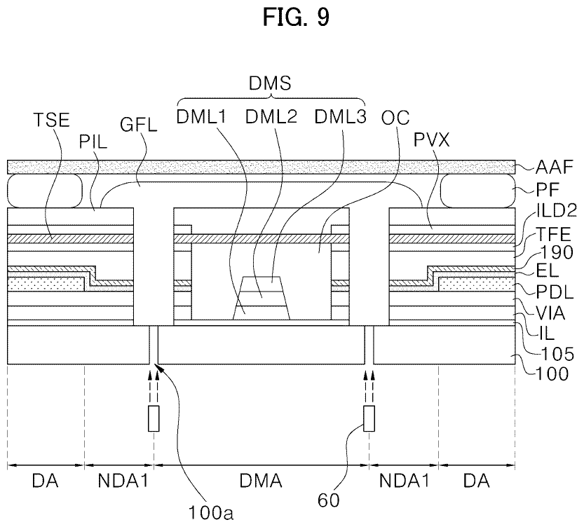

Referring to FIG. 9, the etchant solution may be sprayed through the etching line SKL. According to an embodiment, an etchant supplier 60 may be disposed under the bottom surface of the substrate 100, and the etchant solution may be sprayed through the etching line SKL. Accordingly, an etched region 100a from which the substrate 100 is partially removed may be formed along the etching line SKL.

For example, the etchant solution may include a hydrofluoric acid solution capable of etching a glass substrate.

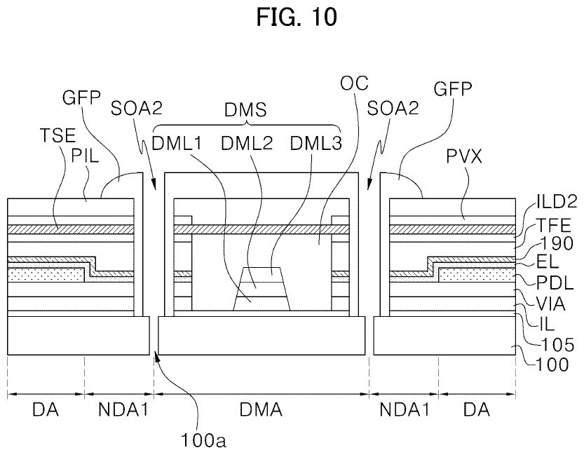

Referring to FIG. 10, the gap-fill layer GFL may be partially removed by a second partial removal process.

According to an embodiment, the protective film PF and the acid resistant film AAF may be removed, and portions of the gap-fill layer GFL at the boundary region between the first non-display area NDA1 and the dummy area DMA may be removed. Accordingly, a second sub-opening SOA2 exposing the etched region 100a may be formed.

The second sub-opening SOA2 may have a width smaller than that of the first sub-opening SOA1. The second sub-opening SOA2 may overlap the etched region 100a in the plan view over the planarization layer PIL. Accordingly, the second sub-opening SOA2 may be connected to the etched region 100a.

The second partial removal process may include the laser ablation process or the photo-lithography process as described above.

Thereafter, the dummy area DMA and the structures remaining on the dummy area DMA may be separated/removed by using the second sub-opening SOA2 and the etched region 100a. Accordingly, as illustrated in FIGS. 3 and 4, the opening OA may be formed in a space from which the dummy area DMA is removed, and the circumference of the opening OA may be defined by the gap-fill pattern GFP remaining from the gap-fill layer GFL.

According to an embodiment of the present invention described above, the first sub-opening SOA1 may be formed by the first partial removal process before the formation of the etching line SKL. Accordingly, damages to the buffer layer 105 and the insulation layer IL formed on the top surface of the substrate 100 may be prevented during a laser sketching process.

Further, the gap fill layer GFL may be formed in the first sub-opening SOA1 to prevent the etchant solution from penetrating into the first non-display area NDA1 to cause peel-off and damages of layers. For example, corrosion/damage of the dam structure DMP and the tip structure TIP1 and TIP2 due to penetration of the etchant solution may be prevented.

Additionally, the gap-fill layer GFL may be partially removed by the second partial removal process so that the dummy area DMA may be easily removed. Thus, peel-off and detachment of layers included in the first non-display area NDA1 together with the gap fill layer GFL may be prevented when the dummy area DMA is separated.

The hole-shaped opening OA included in the display area DA may be formed with high reliability and stability when the dummy area DMA is separated.

As will be described later, the opening forming process according to example embodiments may also be used in a separation process of individual display elements or display panels.

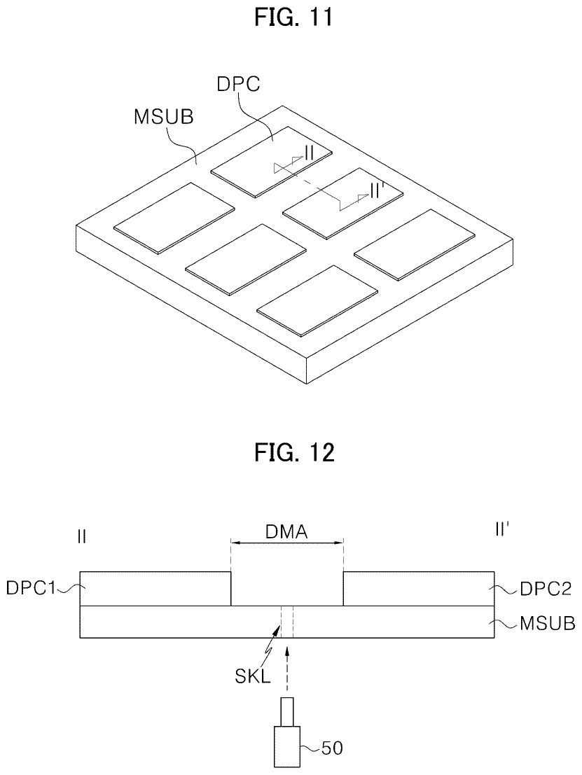

FIG. 11 is a schematic perspective view illustrating a method of manufacturing a display device according to embodiments. FIGS. 12 to 15 are schematic cross-sectional views illustrating a method of manufacturing a display device according to embodiments. Specifically, FIGS. 12 to 15 are cross-sectional views taken along a line II-II′ of FIG. 11 in a thickness direction.

Detailed descriptions on processes and materials substantially the same as or similar to those described with reference to FIGS. 5 to 10 will be omitted.

Referring to FIG. 11, a plurality of display device cells DPC may be formed on a mother substrate MSUB. Each of the display device cells DPC may include the display area DA and non-display areas NDA1 and NDA2 described with reference to FIG. 3. Each of the display device cells DPC may include the circuit structure and the display element described with reference to FIG. 3. A preliminary display device may be defined by the mother substrate MSUB and a plurality of display device cells DPC. The preliminary display device may be separated from each other and become individual display devices.

Referring to FIG. 12, a laser from a laser light source 50 may be irradiated through a bottom surface of the mother substrate MSUB overlapping a dummy area DMA between a first display device cell DPC1 and a second display device cell DPC2. Accordingly, an etching line SKL may be formed in a portion of the mother substrate MSUB overlapping the dummy area DMA.

In an embodiment, a portion of the display device cell DPC around the dummy area DMA may be removed by the first partial removal process described above. Accordingly, damages to the end portion of the display device cell DPC due to the laser irradiation may be prevented.

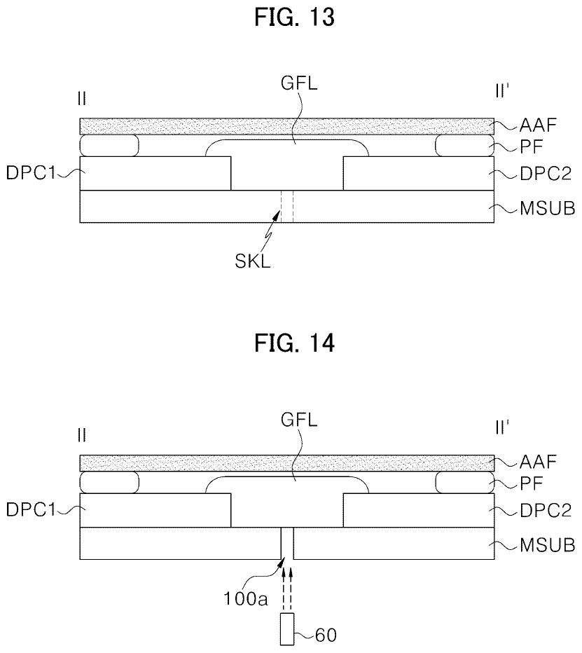

Referring to FIG. 13, a gap-fill layer GFL filling the dummy are DMA may be formed. The gap-fill layer GFL may be formed on top surfaces of the display device cells DPC while sufficiently filling the dummy area DMA.

Thereafter, the acid resistant film AAF covering the first display device cell DPC1 and the second display device cell DPC2 may be attached using a protective film PF.

Referring to FIG. 14, the etchant solution may be supplied from the bottom surface of the mother substrate MSUB by using an etching solution supplier 60. Accordingly, an etched region 100a penetrating the mother substrate MSUB may be formed.

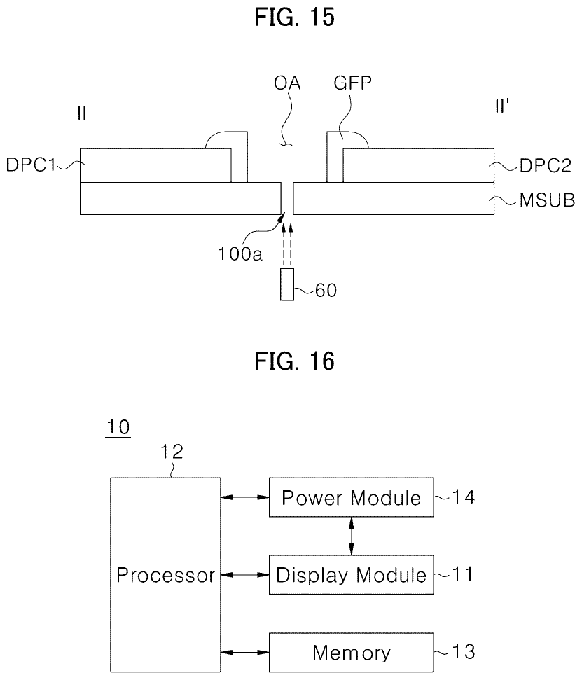

Referring to FIG. 15, the protective film PF and the acid resistant film AAF may be removed, and a portion of the gap-fill layer GFL overlapping the etched region 100a may be removed. Accordingly, the opening OA connected to the etched region 100a may be formed in the removed portion of the gap-fill layer GFL. A panel separation through which the first display device cell DPC1 and the second display device cell DPC2 are separated may be implemented by using the opening OA and the etched region 100a.

A gap-fill pattern GFP remaining on a top surface of the mother substrate MSUB and on a sidewall of each of the first display device cell DPC1 and the second display device cell DPC2 may be formed from the gap-fill layer GFL.

FIG. 16 is a block diagram of an electronic device according to an embodiment.

Referring to FIG. 16, an electronic device 10 according to an embodiment may include a display module 11, a processor 12, a memory 13 and a power module 14.

The processor 12 may include a central processing unit (CPU), an application processor (AP), a graphic processing unit (GPU), a communication processor (CP), an image signal processor (ISP) and/or a controller.

Data information necessary for an operation of the processor 12 or the display module 11 may be stored in the memory 13. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device, and a power conversion module that converts a power supplied by the power supply module to a generate power required for the operation of the electronic device 10.

At least one of the above-described components of the electronic device 10 may be included in the display device according to the above-described embodiments. Additionally, some of individual modules functionally included in one module may be included in the display device, and others may be provided separately from the display device. For example, the display device may include the display module 11, and the processor 12, the memory 13 and the power module 14 may be provided in the form of another device in the electronic device 10 different from the display device.

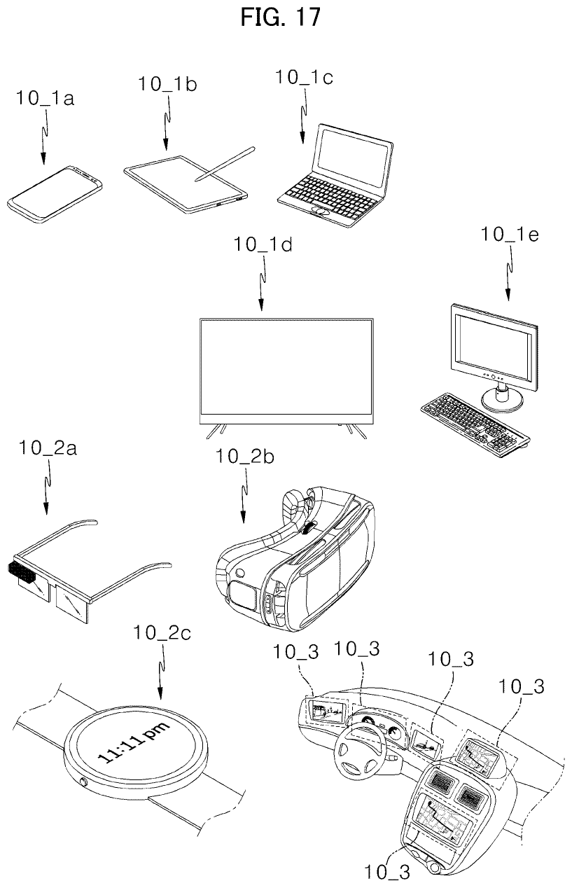

FIG. 17 is a schematic diagram of electronic devices according to various embodiments.

Referring to FIG. 17, non-limiting examples of various electronic devices to which the display device according to embodiments is applied may include not only an electronic device for displaying an image such as a smartphone 10_1a, a tablet PC 10_1b, a laptop 10_1c, a TV 10_1d, a desk monitor 10_1e, or the like, but also a wearable electronic device including a display module such as smart glasses 10_2a, a head mounted display 10_2b, a smart watch 10_2c, or the like. The electronic device to which the display device according to embodiment is applied may further include a vehicle electronic device 10_3 including a display module such as a center information display (CID) disposed at a vehicle instrument panel, a center fascia, a dashboard, etc., a head-up display, a room mirror display, or the like. The electronic device may include a virtual reality glass or an augmented reality glass.

Although certain embodiments have been described herein, other embodiments and variations may be derived from the above description. Accordingly, it should be noted that the above-described embodiments are for the purpose of description and are not intended to limit the meaning and the scope of the disclosure described in claims. In addition, those skilled in the art may understand that various modifications are possible within the scope of the technical spirit of the disclosure as set forth in the following claims.

What is claimed is:

1. A display device, comprising:
a substrate including a display area, an opening, and a non-display area between the opening and the display area;
a display element disposed on the display area of the substrate;
an organic insulation layer and an inorganic insulation layer stacked on the non-display area of the substrate; and
a gap-fill pattern disposed on an end portion of the non-display area adjacent to the opening of the substrate,
wherein the gap-fill pattern is in contact with at least one end portion of the organic insulation layer and the inorganic insulation layer.

2. The display device of claim 1, wherein the opening penetrates the substrate and extends along an outer sidewall of the gap-fill pattern.

3. The display device of claim 2, wherein the gap-fill pattern has a hollow cylindrical shape.

4. The display device of claim 1, wherein the gap-fill pattern contacts a top surface of the substrate.

5. The display device of claim 1, wherein the inorganic insulation layer comprises an encapsulation layer covering the display element on the display area, and the gap-fill pattern is in contact with an end portion of the encapsulation layer.

6. The display device of claim 5, wherein the organic insulation layer comprises an overcoating layer formed on the encapsulation layer, and the gap-fill pattern is in contact with a side surface of the overcoating layer.

7. The display device of claim 5, further comprising a dam structure and a tip structure arranged on the non-display area of the substrate,
wherein the encapsulation layer covers the dam structure and the tip structure.

8. The display device of claim 7, wherein the display element comprises a pixel electrode, a counter electrode, and a light-emitting portion between the pixel electrode and the counter electrode, and
a residual layer of the counter electrode and a residual layer of the light-emitting portion remain under the encapsulation layer on an end portion of the non-display area, and the gap-fill pattern covers side surfaces of the residual layers of the counter electrode and the light-emitting portion.

9. The display device of claim 5, wherein the organic insulation layer comprises a planarization layer arranged on the encapsulation layer, and the planarization layer commonly covers the display area and the non-display area.

10. The display device of claim 9, wherein the gap-fill pattern partially covers a top surface of the planarization layer.

11. The display device of claim 1, wherein the organic insulation layer or the inorganic insulation layer includes a stepped portion on the end portion of the non-display area adjacent to the opening of the substrate, and the gap-fill pattern covers the stepped portion.

12. A method of manufacturing a display device, comprising:
preparing a preliminary display device that comprises a substrate including a display area and a dummy area, and a display element on the display area of the substrate;
forming a gap-fill layer at least partially filling the dummy area;
partially etching the substrate to form an etched region overlapping the gap-fill layer; and
partially removing the gap-fill layer to form an opening connecting to the etched region of the substrate.

13. The method of claim 12, wherein the substrate includes a non-display area between the display area and the dummy area, and the preliminary display device comprises a stacked structure of an organic insulation layer and an inorganic insulation layer formed on the non-display area.

14. The method of claim 13, further comprising removing a portion of the stacked structure around a boundary between the non-display area and the dummy area by a first partial removal process to form a first sub-opening,
wherein the gap-fill layer fills the first sub-opening.

15. The method of claim 14, further comprising irradiating a laser from a bottom surface of the substrate to form an etching line overlapping the first sub-opening before forming the gap-fill layer,
wherein forming the etched region comprises supplying an etching solution through the etching line.

16. The method of claim 14, wherein partially removing the gap-fill layer to form the opening comprises removing a portion of the gap-fill layer overlapping the etched region by a second partial removal process to form the opening.

17. The method of claim 16, wherein forming the opening comprises separating the dummy area using the second sub-opening and the etched region.

18. The method of claim 16, wherein a gap-fill pattern remaining from the gap-fill layer by the second partial removal process is formed on an end portion of the non-display area of the substrate.

19. The method of claim 16, wherein the first partial removal process and the second partial removal process are performed using a laser ablation.

20. An electronic device, comprising:
a display device;
a memory; and
a processor executing data included in the memory and configured to control an operation of the display device,
wherein the display device comprises:
a substrate including a display area, an opening, and a non-display area between the opening and the display area;
a display element disposed on the display area of the substrate;
an organic insulation layer and an inorganic insulation layer stacked on the non-display area of the substrate; and
a gap-fill pattern disposed on an end portion of the non-display area adjacent to the opening of the substrate,
wherein the gap-fill pattern is in contact with at least one end portion of the organic insulation layer and the inorganic insulation layer.
